(19) United States
(12) Patent Application Publication
(10) Pub. No.: US 2025/0279077 A1
(43) Pub. Date: Sep. 4, 2025

(54) DISPLAY AND DISPLAY MANUFACTURING METHOD

(71) Applicant: QISDA CORPORATION, Taoyuan City (TW)

(72) Inventors: Bing-Hann Leu, Taoyuan City (TW); Ying-Fang Lin, Taoyuan City (TW); Ching-Tze Huang, Taoyuan City (TW); Jung-Kun Tseng, Taoyuan City (TW); Cheng-Chieh Juan, Taoyuan City (TW)

(73) Assignee: QISDA CORPORATION, Taoyuan City (TW)

(21) Appl. No.: 19/015,675

(22) Filed: Jan. 10, 2025

(30) Foreign Application Priority Data
Mar. 4, 2024 (CN) 202410242327.3

(51) Int. Cl. G09G 3/34; H10H 29/01; H10H 29/34

(52) U.S. Cl. CPC G09G 3/3426; G09G 3/3413; H10H 29/012; H10H 29/34; G09G 2320/0233; G09G 2320/0242

(57) ABSTRACT

A display having a related manufacturing method includes some pixel regions and a controller. Each pixel region includes a plurality of lighting units arranged as a matrix and respectively having a plurality of wavelength parameters. An arrangement rule of the plurality of wavelength parameters of one of the pixel regions is similar to an arrangement rule of the plurality of wavelength parameters of another pixel region. The controller is electrically connected to the pixel regions and adapted to change a distance between two adjacent lighting units of the pixel regions. An average intensity difference between two adjacent pixel regions inside the display is smaller than or equal to five percent. An average chroma difference between two adjacent pixel regions inside the display is smaller than or equal to 0.01.

### BACKGROUND OF THE INVENTION

### 1. Field of the Invention

The present invention relates to a display and a related display manufacturing method, and more particularly, to a display with the preferred image uniformity and a related display manufacturing method.

### 2. Description of the Prior Art

The display includes a lot of light emitting diodes to provide backlight. The light emitting diodes are arranged as an array according to the panel size of the display; however, the conventional technology is difficult to control uniformity in the manufacturing process of the light emitting diodes, and the light emitting diodes at different positions in the display have different wavelengths, and the wavelength distribution range may reach the level of more than ten nanometers. Human vision is sensitive to color; if the wavelength difference between the adjacent light emitting diodes with the same color reaches 1˜2 nanometers, the wavelength difference is easily recognized and the image uniformity is destroyed accordingly. For preventing the wavelength difference of the light emitting diodes from affecting the image quality of the display, the conventional technology manufactures the display by the light emitting diodes with the narrow wavelength range, but has drawbacks of low utilization, time-consuming selection, and high cost. In addition, the conventional technology further arranges the light-emitting diodes with different wavelengths via the random model, the display is manufactured by the light emitting diodes with the wider wavelength distribution range, but has drawbacks of limited affect and unstable image quality. Therefore, design of a display and a related display manufacturing method of utilizing the light emitting diodes with the wider wavelength distribution range to provide the preferred image uniformity and the stable image quality is an important issue in the display industry.

### SUMMARY OF THE INVENTION

The present invention provides a display with the preferred image uniformity and a related display manufacturing method for solving above drawbacks.

According to the claimed invention, a display includes multiple pixel regions and a controller. Each of the multiple pixel regions includes a plurality of lighting units arranged as an array and has a plurality of wavelength parameters respectively. An arrangement rule of the plurality of wavelength parameters of one pixel region of the multiple pixel regions is similar to an arrangement rule of the plurality of wavelength parameters of another pixel region of the multiple pixel regions. The controller is electrically connected to the multiple pixel regions and adapted to change an interval between two adjacent lighting units of the multiple pixel regions. An average intensity difference between adjacent pixel regions of the multiple pixel regions is smaller than or equal to five percent. An average chroma difference between adjacent pixel regions of the multiple pixel regions is smaller than or equal to 0.01.

According to the claimed invention, the display further includes a distance detector electrically connected to the controller and adapted to detect a target object in front of the display. The controller is adapted to further change the interval in accordance with a relative distance between the target object and the display. The controller is adapted to turn off at least one of the plurality of lighting units that has the wavelength parameter conforms to a preset condition for changing the interval. The plurality of wavelength parameters of the plurality of lighting units is divided into multiple wavelength levels in accordance with a preset wavelength range, the preset condition is represented as a wavelength level of the at least one lighting unit is a highest wavelength level and/or a lowest wavelength level of the multiple wavelength levels. The controller is adapted to compare the relative distance with a preset distance threshold, and decides a turn-off ratio of the at least one lighting unit in accordance with a comparison result.

According to the claimed invention, the display further includes a driving module electrically connected to the multiple pixel regions and the controller. The controller is adapted to further drive the driving module to move at least one of the multiple pixel regions for changing the interval. The driving module includes a multiple driving units respectively disposed on the multiple pixel regions and adapted to control movements of the multiple pixel regions. The driving module includes a plurality of driving units respectively disposed on the plurality of lighting units of the at least one pixel region, and adapted to control movements of the plurality of lighting units. The controller is adapted to compare the relative distance with a preset distance threshold, and decide a moving distance of the at least one pixel region in accordance with a comparison result.

According to the claimed invention, the multiple pixel regions are sequentially arranged in a horizontal direction or a vertical direction or an oblique direction of the display, and the arrangement rule of the plurality of wavelength parameters has periodic change. A central target wavelength of the plurality of wavelength parameters is defined by wavelength distribution of the plurality of lighting units and/or chromaticity coordinates of the display. The plurality of wavelength parameters of the plurality of lighting units is divided into multiple wavelength levels based on the central target wavelength in accordance with a preset wavelength range, and each pixel region comprises the plurality of lighting units that has the plurality of wavelength parameters with two or more than two wavelength levels.

According to the claimed invention, a wavelength level of one lighting unit is different from a wavelength level of another adjacent lighting unit within each pixel region. The preset wavelength range is smaller than or equal to one nanometer when the plurality of lighting units is blue light emitting diodes or red light emitting diodes, and the preset wavelength range is smaller than or equal to two nanometers when the plurality of lighting units is green light emitting diodes.

According to the claimed invention, a wavelength average difference of a test region of the display that is overlapped with at least two adjacent pixel regions of the multiple pixel regions is smaller than or equal to two nanometers, and a size of the test region is the same as a size of each pixel region. A wavelength average difference of some lighting units contained by each row of each pixel region is smaller than or equal to two nanometers, and a wavelength average difference of some lighting units contained by each column of each pixel region is smaller than or equal to two nanometers.

According to the claimed invention, a display manufacturing method includes manufacturing a first pixel region by a plurality of first lighting units in accordance with an arrangement rule, manufacturing a second pixel region by a plurality of second lighting units in accordance with the arrangement rule, disposing the first pixel region adjacent to the second pixel region, acquiring a relative distance between a target object and a display detected by a distance detector, and analyzing a comparison result of the relative distance and a preset distance threshold to decide whether to change an interval between two adjacent lighting units of the plurality of first lighting units and/or the plurality of second lighting units. An average intensity difference between the first pixel region and the second pixel region is smaller than or equal to five percent. An average chroma difference between the first pixel region and the second pixel region is smaller than or equal to 0.01.

The display and the display manufacturing method of the present invention can arrange the lighting units of the pixel regions that have different wavelength parameters via the specific rule, and the display can be made by the multiple pixel regions having the wavelength parameters with the same or similar arrangement rule, so that regions and color and intensity of all the lighting units of the display can have the periodic change with the specific arrangement rule, for providing the preferred image uniformity. In addition, the display and the display manufacturing method of the present invention can utilize the distance detector to optionally turn off the lighting unit conforming to the preset condition, or can utilize the driving module to move the pixel region or the lighting unit in accordance with detection data of the distance detector, so as to prevent uniformity defects from being discovered by the user for improvement of the image uniformity.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a functional block diagram of a display according to an embodiment of the present invention.

FIG. 2 is a diagram of pixel distribution of the display according to the embodiment of the present invention.

FIG. 3 is a diagram of parts of a pixel region according to the embodiment of the present invention.

FIG. 4 to FIG. 6 are diagrams of one pixel region of the display in different application modes according to the embodiment of the present invention.

FIG. 7 to FIG. 9 are diagrams of the multiple pixel regions of the display in different application modes according to another embodiment of the present invention.

FIG. 10 is a flow chart of a display manufacturing method according to the embodiment of the present invention.

### DETAILED DESCRIPTION

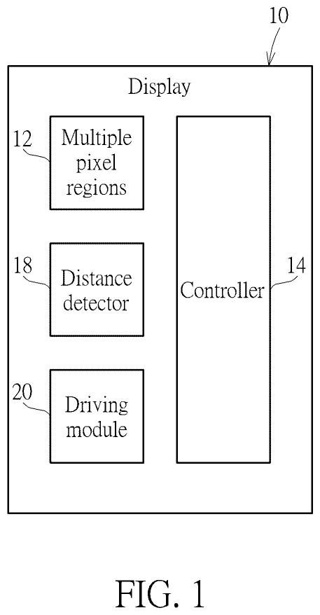

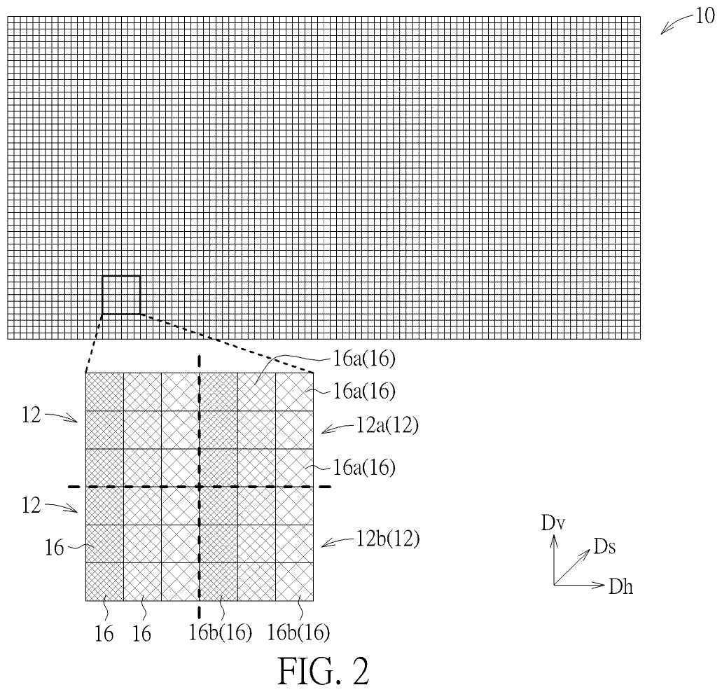

Please refer to FIG. 1 and FIG. 2. FIG. 1 is a functional block diagram of a display 10 according to an embodiment of the present invention. FIG. 2 is a diagram of pixel distribution of the display 10 according to the embodiment of the present invention. The display 10 can include multiple pixel regions 12, a controller 14 and other electronic components. The said electronic components are not design focus of the present invention, and a detailed description is omitted herein for simplicity. Each pixel region 12 can include a plurality of lighting units 16 arranged as an array and respectively having a plurality of wavelength parameters. In the embodiment, the pixel region 12 has nine lighting units 16 arranged as the 3×3 array, and practical application of a number of the lighting unit 16 is not limited to the foresaid embodiment. A pixel number and arrangement of the pixel region 12 is not limited to the embodiment shown in FIG. 2, and depends on a design demand.

The lighting unit 16 can be a light emitting diode, or an electronic component with similar functions. Due to process limitation of the light emitting diode, the lighting units 16 of each pixel region 12 may have different wavelength parameters, and the display 10 of the present invention can arrange the lighting units 16 of all the pixel regions 12 via a specific rules, which means an arrangement rule of the wavelength parameters of the lighting units 16 inside each pixel region 12 can be the same as the arrangement rule of the wavelength parameters of the lighting units 16 inside another pixel region 12. Therefore, when the multiple pixel regions 12 are adjacently arranged in a horizontal direction Dh, a vertical direction Dv and an oblique direction Ds of the display 10, the lighting units 16 of the display 10 can have periodic change of the wavelength parameters based on a size of each pixel region 12, and the display 10 can have preferred image uniformity.

Besides, the display 10 can preferably design that an average intensity difference between adjacent pixel regions 12 of all the pixel regions 12 is smaller than or equal to five percent, and an average chroma difference between the adjacent pixel regions 12 of all the pixel regions 12 is smaller than or equal to 0.01; therefore, the lighting units 16 applied to the display 10 are not limited to the light emitting diodes with a narrow wavelength range. The display 10 of the present invention can have the pixel regions 12 with the wavelength parameters arranged as the periodic change. Compared with the prior art in which wavelength parameters are arranged randomly, the display 10 of the present invention can use the light emitting diodes with a wider wavelength range, and have advantages of the low manufacturing cost and the preferred image uniformity.

The lighting unit 16 can mainly include a blue light emitting diode, a green light emitting diode and a red light emitting diode. The wavelength parameter of the blue light emitting diode can be ranged between 430˜480 nanometers. The wavelength parameter of the green light emitting diode can be ranged between 520˜540 nanometers. The wavelength parameter of the red light emitting diode can be ranged between 620˜630 nanometers. The lighting units 16 of each pixel region 12 mentioned as above can have the periodic arrangement in accordance with the wavelength parameters, and the present invention can set a central target wavelength in accordance with wavelength distribution of all the lighting units 16, so that the lighting units 16 of each pixel region 12 having different wavelength parameters can be periodically arranged based on the central target wavelength. The central target wavelength can be set in accordance with the wavelength range of the light emitting diode, and the detailed description is omitted herein for simplicity. Further, the present invention may optionally compute chromaticity coordinates of the display 10 to decide the central target wavelength; parameter of the chromaticity coordinates can depend on the model or the brand of the display 10, and the detailed description is omitted herein for simplicity.

In addition to the central target wavelength, the present invention can optionally choose a preset wavelength range in accordance with color features of the lighting unit 16, and utilize the preset wavelength range and the central target wavelength to divide the wavelength parameters of the lighting units 16 of each pixel region 12 into multiple wavelength levels; the periodic change of the wavelength parameter can be presented in units of the size of each pixel region 12. For example, the preset wavelength ranges of the blue light emitting diode and the red light emitting diode can be preferably smaller than or equal to one nanometer, and the preset wavelength range of the green light emitting diode can be preferably smaller than or equal to two nanometers; practical application of values of the preset wavelength range is not limited to the foresaid embodiment.

It should be mentioned that each pixel region 12 can preferably include the lighting units 16 having the wavelength parameters with two or more than two wavelength levels, and the wavelength level of any lighting unit 16 can be preferably different from the wavelength level of the adjacent lighting units 16 within the pixel region 12, which means the lighting units 16 that have the wavelength parameters classified into the same wavelength level cannot be placed side by side, and therefore the display 10 can have the preferred image uniformity due to the periodic change of the wavelength parameters. Besides, the present invention can further have the following design: a wavelength average difference of the lighting units 16 contained by each row of the pixel region 12 can be preferably smaller than or equal to two nanometers, and a wavelength average difference of the lighting units 16 contained by each column of the pixel region 12 can be preferably smaller than or equal to two nanometers.

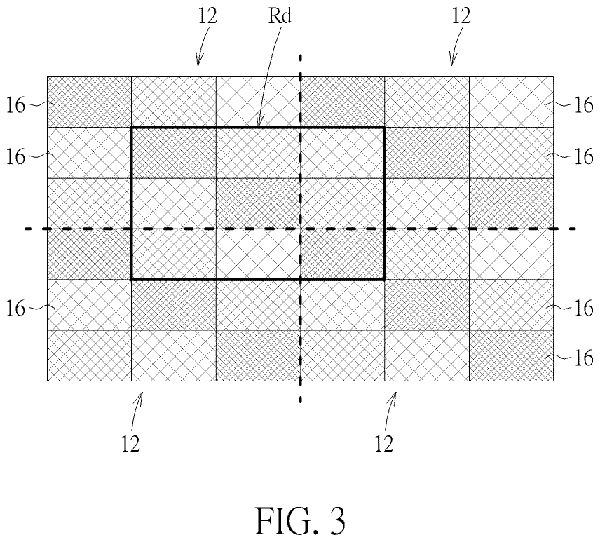

Please refer to FIG. 3. FIG. 3 is a diagram of parts of the pixel region 12 according to the embodiment of the present invention. As shown in FIG. 3, four pixel regions 12 are arranged adjacent to each other, and the arrangement rule of the wavelength parameters of the lighting units 16 within each pixel region 12 can be the same as the arrangement rule of the wavelength parameters of the lighting units 16 within another pixel region 12; the grid density can be varied to represent different wavelength parameters. Moreover, the present invention can randomly draw a test region Rd on the multiple pixel regions 12 of the display 10; a size of the test region Rd can be preferably the same as a size of the pixel region 12, and practical application of the size relation is not limited to the foresaid embodiment. The test region Rd may be completely overlapped with one pixel region 12, or may be partly overlapped with two or more adjacent pixel regions 12 at the same time; for example, the test region Rd shown in FIG. 3 can be overlapped with four pixel regions 12. No matter where the test region Rd is located on the display 10, the wavelength average difference of all the lighting units 16 within the test region Rd of the present invention can be preferably smaller than or equal to two nanometers, and the average chroma difference of the adjacent pixel regions 12 can be smaller than or equal to 0.01, so as to dilute texture caused by the periodic change of the wavelength parameters.

The controller 14 can be electrically connected to all the pixel regions 12 of the display 10, and can change an interval between the adjacent lighting units 16 of all the pixel regions 12. One way of changing the interval can turn off parts of the lighting units 16, for visually changing the interval between the adjacent lighting units 16 in the turn-on mode. Another way of changing the interval can move the lighting unit 16 in the turn-on mode. The display 10 can optionally include a distance detector 18 and a driving module 20. The distance detector 18 can be electrically connected to the controller 14, and used to detect the target object in front of the display 10. The driving module 20 can be electrically connected to the pixel region 12 and the controller 14. The controller 14 can switch the lighting unit 16 into the turn-on mode or the turn-off mode, or utilize the driving module 20 to move the pixel region 12 and/or the lighting unit 16 in accordance with the relative distance between the target object and the display 10, so as to change the interval between the adjacent lighting units 16 of all the pixel regions 12 of the display 10.

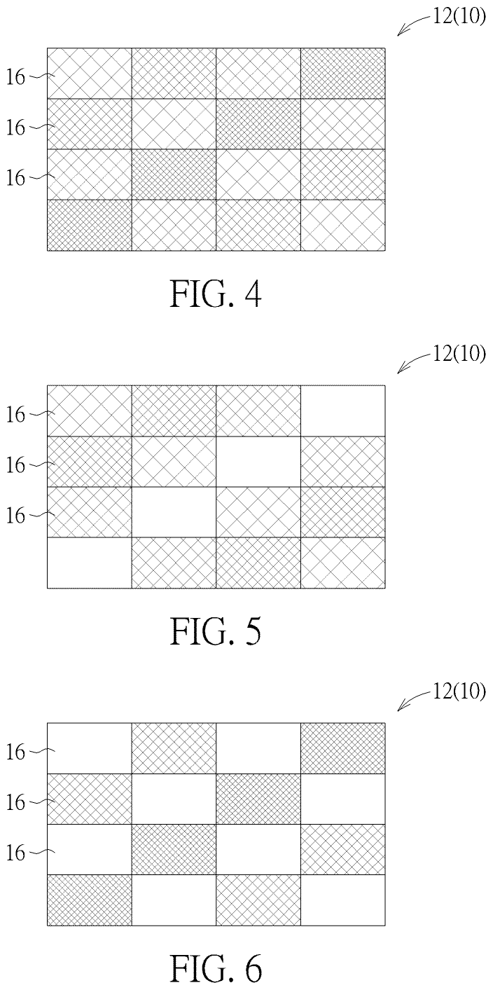

Please refer to FIG. 4 to FIG. 6. FIG. 4 to FIG. 6 are diagrams of one pixel region 12 of the display 10 in different application modes according to the embodiment of the present invention. As mentioned above, the wavelength parameters of all the lighting units 16 of the display 10 can be divided into the multiple wavelength levels via the preset wavelength range, and the lighting unit 16 that belongs to an extreme level (such as a highest wavelength level and/or a lowest wavelength level) of the multiple wavelength levels can be defined as conforming to a preset condition. Therefore, the display 10 of the present invention can utilize the distance detector 18 to acquire the relative distance between the target object and the display 10, and compare the relative distance with the preset distance threshold, so as to decide a turn-off number or a turn-off ratio of the lighting units 16 in accordance with a comparison result. The preset distance threshold can be defined as: a standard distance at which the user (which means the target object) watches the display 10 in accordance with the size of the display 10, and the detailed description is omitted herein for simplicity.

As shown in FIG. 4, if the relative distance between the target object and the display 10 is similar to the preset distance threshold, the user can be located at the preset standard distance, and the display 10 can keep all the lighting units 16 in the turn-on mode and not turn off any lighting unit 16. As shown in FIG. 5, if the relative distance is within a range of one to two times the preset distance threshold, the display 10 can optionally turn off a first proportion of the lighting units 16, and the wavelength parameter of the turned-off lighting unit 16 can conform to the preset condition; the first proportion may be 25 percentages. As shown in FIG. 6, if the relative distance is greater than two times the preset distance threshold, the display 10 can optionally turn off a second proportion of the lighting units 16 that have the wavelength parameter conforming to the preset condition; the second proportion may be 50 percentages. The turned-off lighting unit 16 can be represented by a blank pattern; definition of the extreme level, the first proportion and the second proportion are not limited to the foresaid embodiment, and depend on the design demand.

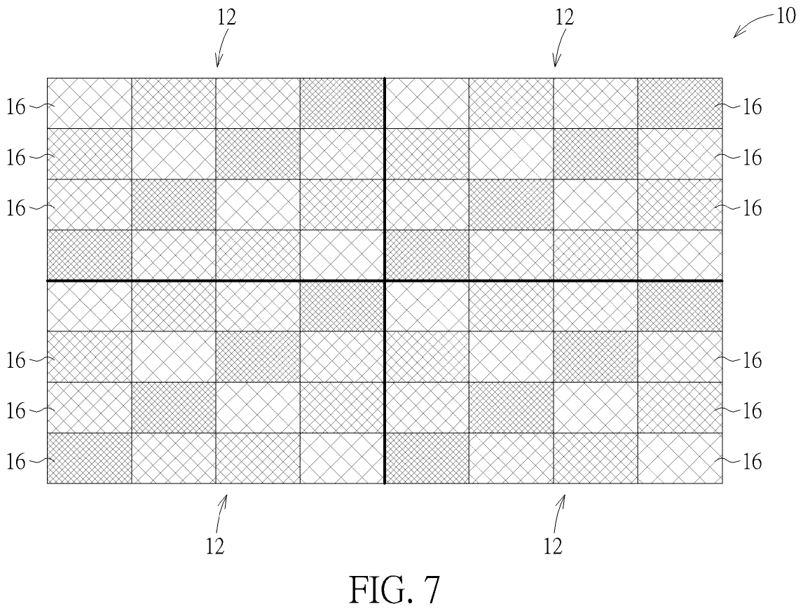

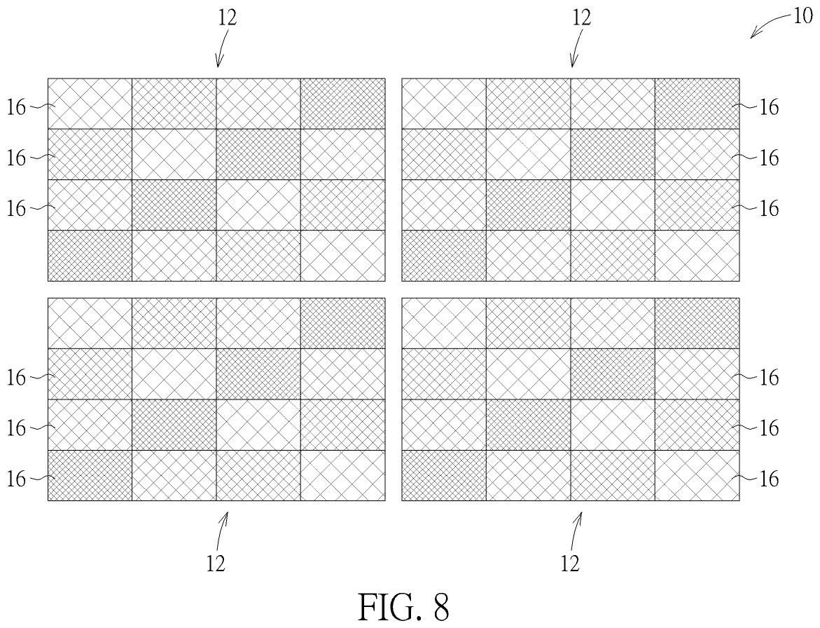

Please refer to FIG. 7 to FIG. 9. FIG. 7 to FIG. 9 are diagrams of the multiple pixel regions 12 of the display 10 in different application modes according to another embodiment of the present invention. As shown in FIG. 7, the relative distance between the target object and the display 10 can be similar to the preset distance threshold, and the display 10 does not change relative position of the multiple pixel regions 12. As shown in FIG. 8, driving units (which are not marked in the figures) of the driving module 20 can be respectively disposed on the multiple pixel regions 12 of the display 10, and the controller 14 can decide a moving distance of each pixel region 12 in accordance with a comparison result of the relative distance and the preset distance threshold. For example, if the relative distance is within the range of one to two times the preset distance threshold, the display 10 can control the pixel region 12 to move by a first preset interval; if the relative distance is greater than two times the preset distance threshold, the display 10 can control the pixel region 12 to move by a second preset interval. The second preset interval may be twice the first preset interval, and the actual application is not limited thereto.

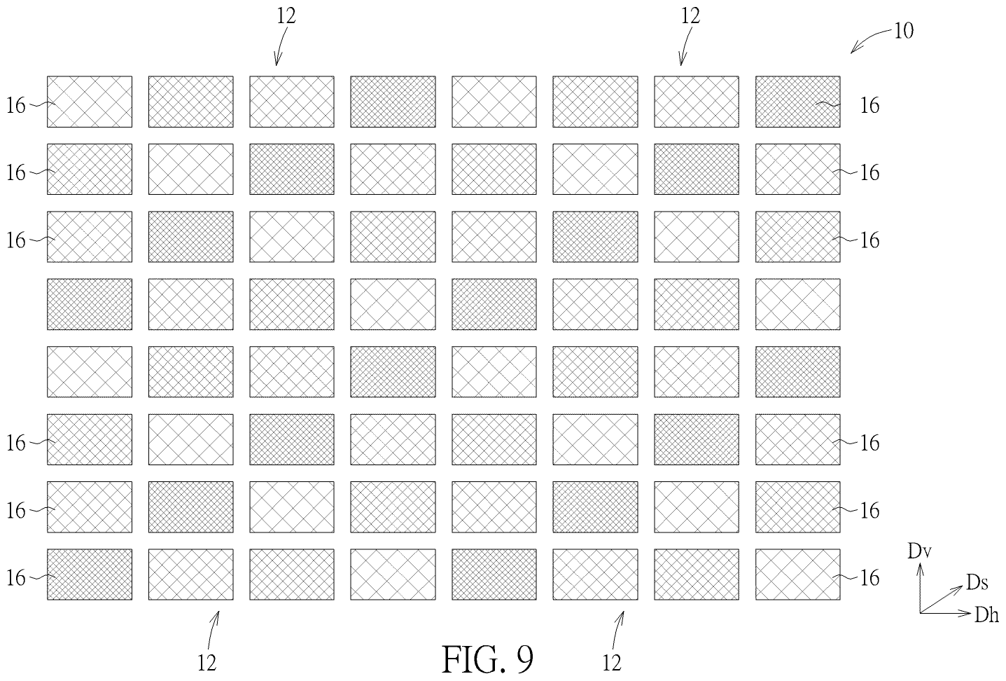

As shown in FIG. 9, the driving units (which are not marked in the figures) of the driving module 20 can be respectively disposed on all the lighting units 16 of the multiple pixel regions 12 of the display 10, and the controller 14 can decide the moving distance of each lighting unit 16 in accordance with the comparison result of the relative distance and the preset distance threshold, such as the first preset interval and the second preset interval. Please refer to FIG. 2 and FIG. 9. The pixel regions 12 and the related lighting units 16 of the display 10 can be sequentially arranged in the horizontal direction Dh, in the vertical direction Dv or in the oblique direction Ds of the display 10, so that the arrangement rule of the wavelength parameters of all the pixel regions 12 of the display 10 can have the periodic change. Accordingly, the present invention can utilize the driving module 20 to move the pixel region 12 and/or the lighting unit 16 in the horizontal direction Dh, the vertical direction Dv or the oblique direction Ds, so as to achieve an aim of changing the interval between the adjacent lighting units 16 of different pixel regions 12.

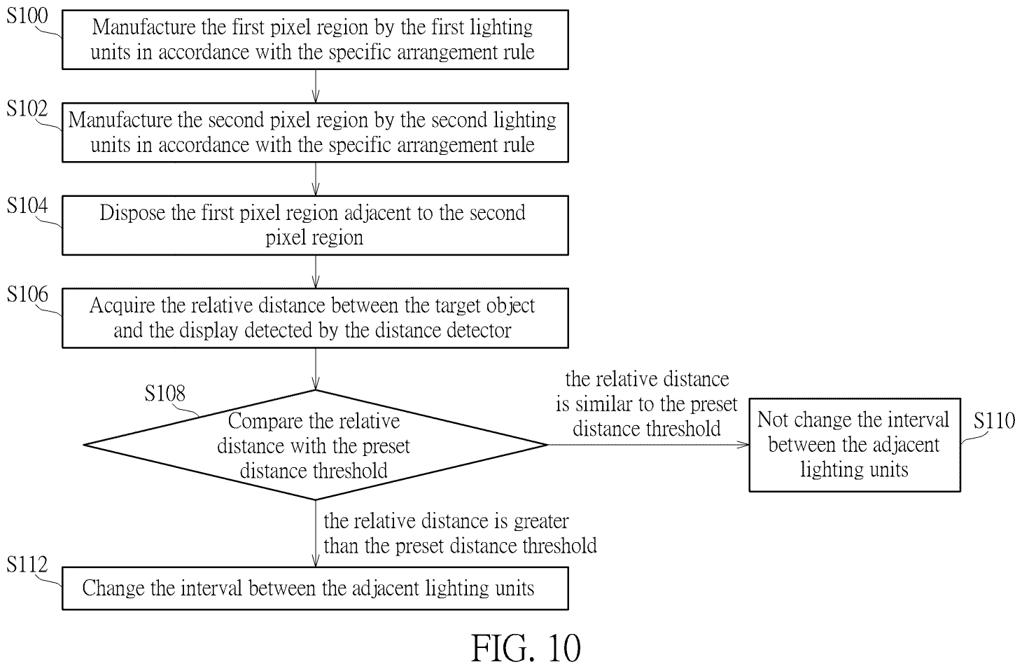

Please refer to FIG. 1, FIG. 2 and FIG. 10. FIG. 10 is a flow chart of a display manufacturing method according to the embodiment of the present invention. The display manufacturing method illustrated in FIG. 10 can be suitable for the display 10 shown in FIG. 1 and FIG. 2. The display manufacturing method takes two pixel regions 12 as an example. First, step S100 and step S102 can be executed to manufacture a first pixel region 12a by the first lighting units 16a in accordance with the specific arrangement rule, and manufacture a second pixel region 12b by the second lighting units 16b in accordance with the specific arrangement rule. A shape of each pixel region 12 can be a square array, a rectangular array, a diamond array, or any other shapes. The arrangement rule can be the periodic change of the wavelength parameters along the horizontal direction Dh, the vertical direction Dv or the oblique direction Ds. Then, step S104 can be executed to dispose the first pixel region 12a adjacent to the second pixel region 12b; if step S100 and step S102 are executed multiple times, step S104 can increase a number of the multiple pixel regions 12 arranged adjacently.

Then, step S106 and step S108 can be executed to acquire the relative distance between the target object and the display 10 detected by the distance detector 18, and then to compare the relative distance with the preset distance threshold. If the relative distance is similar to the preset distance threshold, step S110 can be executed to not change the interval between the adjacent lighting units 16. If the relative distance is much greater than the preset distance threshold, step S112 can be executed to change the interval between the adjacent lighting units 16. In step S112, the display manufacturing method can turn off some lighting unit 16 of the first lighting unit 16a and/or the second lighting unit 16b that have the wavelength parameter conforming to the preset condition for changing the interval, or can utilize the driving module 20 to move the first pixel region 12a and/or the second pixel region 12b, or to move a part of the first lighting unit 16a of the first pixel region 12a and/or a part of the second lighting unit 16b of the second pixel region 12b, for changing the interval.

In conclusion, the display and the display manufacturing method of the present invention can arrange the lighting units of the pixel regions that have different wavelength parameters via the specific rule, and the display can be made by the multiple pixel regions having the wavelength parameters with the same or similar arrangement rule, so that regions and color and intensity of all the lighting units of the display can have the periodic change with the specific arrangement rule, for providing the preferred image uniformity. In addition, the display and the display manufacturing method of the present invention can utilize the distance detector to optionally turn off the lighting unit conforming to the preset condition, or can utilize the driving module to move the pixel region or the lighting unit in accordance with detection data of the distance detector, so as to prevent uniformity defects from being discovered by the user for improvement of the image uniformity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A display comprising
multiple pixel regions, each of the multiple pixel regions comprising a plurality of lighting units arranged as an array and respectively having a plurality of wavelength parameters, an arrangement rule of the plurality of wavelength parameters of one pixel region of the multiple pixel regions being similar to an arrangement rule of the plurality of wavelength parameters of another pixel region of the multiple pixel regions; and
a controller electrically connected to the multiple pixel regions and adapted to change an interval between two adjacent lighting units of the multiple pixel regions;
wherein an average intensity difference between adjacent pixel regions of the multiple pixel regions is smaller than or equal to five percent;
wherein an average chroma difference between adjacent pixel regions of the multiple pixel regions is smaller than or equal to 0.01.

2. The display of claim 1, further comprising:
a distance detector electrically connected to the controller and adapted to detect a target object in front of the display, the controller being adapted to further change the interval in accordance with a relative distance between the target object and the display.

3. The display of claim 2, wherein the controller is adapted to turn off at least one of the plurality of lighting units that has the wavelength parameter conforms to a preset condition for changing the interval.

4. The display of claim 3, wherein the plurality of wavelength parameters of the plurality of lighting units is divided into multiple wavelength levels in accordance with a preset wavelength range, the preset condition is represented as a wavelength level of the at least one lighting unit is a highest wavelength level and/or a lowest wavelength level of the multiple wavelength levels.

5. The display of claim 3, wherein the controller is adapted to compare the relative distance with a preset distance threshold, and decides a turn-off ratio of the at least one lighting unit in accordance with a comparison result.

6. The display of claim 2, wherein the display further comprises a driving module electrically connected to the multiple pixel regions and the controller, the controller is adapted to further drive the driving module to move at least one of the multiple pixel regions for changing the interval.

7. The display of claim 6, wherein the driving module comprises a multiple driving units respectively disposed on the multiple pixel regions and adapted to control movements of the multiple pixel regions.

8. The display of claim 6, wherein the driving module comprises a plurality of driving units respectively disposed on the plurality of lighting units of the at least one pixel region, and adapted to control movements of the plurality of lighting units.

9. The display of claim 6, wherein the controller is adapted to compare the relative distance with a preset distance threshold, and decide a moving distance of the at least one pixel region in accordance with a comparison result.

10. The display of claim 1, wherein the multiple pixel regions are sequentially arranged in a horizontal direction or a vertical direction or an oblique direction of the display, and the arrangement rule of the plurality of wavelength parameters has periodic change.

11. The display of claim 1, wherein a central target wavelength of the plurality of wavelength parameters is defined by wavelength distribution of the plurality of lighting units and/or chromaticity coordinates of the display.

12. The display of claim 11, wherein the plurality of wavelength parameters of the plurality of lighting units is divided into multiple wavelength levels based on the central target wavelength in accordance with a preset wavelength range, and each pixel region comprises the plurality of lighting units that has the plurality of wavelength parameters with two or more than two wavelength levels.

13. The display of claim 12, wherein a wavelength level of one lighting unit is different from a wavelength level of another adjacent lighting unit within each pixel region.

14. The display of claim 12, wherein the preset wavelength range is smaller than or equal to one nanometer when the plurality of lighting units is blue light emitting diodes or red light emitting diodes, and the preset wavelength range is smaller than or equal to two nanometers when the plurality of lighting units is green light emitting diodes.

15. The display of claim 1, wherein a wavelength average difference of a test region of the display that is overlapped with at least two adjacent pixel regions of the multiple pixel regions is smaller than or equal to two nanometers, and a size of the test region is the same as a size of each pixel region.

16. The display of claim 1, wherein a wavelength average difference of some lighting units contained by each row of each pixel region is smaller than or equal to two nanometers, and a wavelength average difference of some lighting units contained by each column of each pixel region is smaller than or equal to two nanometers.

17. A display manufacturing method, comprising:
manufacturing a first pixel region by a plurality of first lighting units in accordance with an arrangement rule;
manufacturing a second pixel region by a plurality of second lighting units in accordance with the arrangement rule;
disposing the first pixel region adjacent to the second pixel region;
acquiring a relative distance between a target object and a display detected by a distance detector; and
analyzing a comparison result of the relative distance and a preset distance threshold to decide whether to change an interval between two adjacent lighting units of the plurality of first lighting units and/or the plurality of second lighting units;
wherein an average intensity difference between the first pixel region and the second pixel region is smaller than or equal to five percent;
wherein an average chroma difference between the first pixel region and the second pixel region is smaller than or equal to 0.01.

18. The display manufacturing method of claim 17, further comprising:
turning off at least one of the plurality of first lighting units and/or the plurality of second lighting units that has the wavelength parameter conforms to a preset condition for changing the interval.

19. The display manufacturing method of claim 18, wherein the plurality of wavelength parameters of the plurality of first lighting units and/or the plurality of second lighting units is divided into multiple wavelength levels in accordance with a preset wavelength range, the preset condition is represented as a wavelength level of the at least one lighting unit is a highest wavelength level and/or a lowest wavelength level of the multiple wavelength levels.

20. The display manufacturing method of claim 17, further comprising:
utilizing a driving module electrically connected to the first pixel region and the second pixel region to move at least one of the first pixel region and the second pixel region for changing the interval;
wherein multiple driving units of the driving module are respectively disposed on the first pixel region and the second pixel region for controlling its movements, or a plurality of driving units of the driving module are respectively disposed on the plurality of first lighting units and the plurality of second lighting units for controlling its movements.
